(19) United States
(12) Patent Application Publication
(10) Pub. No.: US 2024/0402245 A1
(43) Pub. Date: Dec. 5, 2024

(54) Techniques For Testing Leakage Current In Input And Output Circuits

(71) Applicant: Altera Corporation, San Jose, CA (US)

(72) Inventors: Chiew Khiang Kuit, Bukit Mertajam (MY); Ching Sia Lim, Jelutong (MY); Ann Poh Gan, Sepang (MY)

(73) Assignee: Altera Corporation, San Jose, CA (US)

(21) Appl. No.: 18/800,444

(22) Filed: Aug. 12, 2024

(51) Int. Cl. G01R 31/28

(52) U.S. Cl. CPC G01R 31/2896

(57) ABSTRACT

An integrated circuit includes an output circuit. The output circuit includes first, second, and third external contacts, a first output buffer circuit coupled to the first external contact, a first resistive circuit coupled between the first external contact and the second external contact, a second output buffer circuit coupled to the third external contact, and a second resistive circuit coupled between the second external contact and the third external contact. The output circuit has a test mode of operation to test for leakage current on the first and the third external contacts in response to receiving a first voltage applied externally to the first and the second resistive circuits through the second external contact. The output circuit has a user mode of operation wherein a supply voltage is applied externally to the first and the second resistive circuits through the second external contact.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram of an integrated circuit (IC) die that includes boundary scan chain (BSC) registers and an N number of input and output (IO) circuits.

FIG. 2A is a diagram that illustrates an example in which an IO circuit contains leakage current to ground.

FIG. 2B is a diagram that illustrates an example of an IO circuit being tested and an equivalent IO circuit.

FIG. 2C is a diagram that illustrates an example of a user leakage current to ground circuit that is an equivalent of the IO circuit of FIG. 2A containing a defect that causes leakage current to ground.

FIG. 3A is a diagram that illustrates an example in which an IO circuit contains leakage current to the supply voltage network.

FIG. 3B is a diagram that illustrates an example of a user circuit that is an equivalent of the IO circuit of FIG. 3A containing a defect that causes leakage current to the supply voltage network.

FIG. 4 is a diagram of an illustrative example of a configurable integrated circuit (IC).

FIG. 5 illustrates a block diagram of a system that can be used to implement a circuit design to be programmed into a programmable logic device using design software.

FIG. 6 is a diagram that depicts an example of a programmable logic device that includes fabric dies and base dies that are connected to one another via microbumps.

FIG. 7 is a block diagram illustrating a computing system configured to implement one or more aspects of the embodiments described herein.

### DETAILED DESCRIPTION

In an integrated circuit (IC), parametric and leakage tests can be performed on external input and output pads of the IC. According to previously known techniques, testers are used to perform measurements for the leakage and parametric tests. The external input and output pads of an integrated circuit are connected to tester channels for these measurements.

An integrated circuit (IC) is often housed in an integrated circuit (IC) package. Non-exposed input and output circuits in an integrated circuit (IC) have no tester channel access. No-touch leakage (NTL) testing can be implemented to screen any defects causing leakage current at an interface external to the IC. NTL testing is commonly used to detect structural defects that cause low resistive paths from a pad of the IC to power (VCC), from a pad of the IC to ground (GND), and from pad-to-pad. NTL testing is also used to detect gross leakage violations in micro-bumps coupled to the IC. However, NTL testing and other previously known methods cannot accurately test leakage current in input and output circuits in an IC housed in an IC package. Without accurate leakage current testing, losses occur due to test stability, and IC production quality is impacted.

According to some examples disclosed herein, weak pull circuitry in an input and output (IO) circuit in an integrated circuit (IC) is used to test leakage current in the IO circuit. The weak pull circuitry is decoupled from the power supply voltage network of the IO circuits in the IC. The weak pull circuitry is coupled to a pad of the IC through a power supply voltage network that is not coupled through conductors in the IC to the power supply voltage network of the IO circuits. If desired, a user of the IC can couple together the power supply voltage networks of the IO circuits and the weak pull circuitry through a circuit board that is coupled to an IC package that houses the IC. The weak pull circuitry can, for example, be coupled through the power supply voltage network to only one external pad of the IC. This external pad of the IC coupled to the weak pull circuitry can be used as a current sensor port, an input for applying a force voltage for testing, and/or a terminal for measuring current using external parametric measurement unit (PMU) equipment to get accurate measurements for one or more of the IO circuits.

One or more specific examples are described below. In an effort to provide a concise description of these examples, not all features of an actual implementation are described herein. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information (e.g., voltage or current) between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs) and programmable logic devices. As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially fewer configurable features than soft logic or no configurable features.

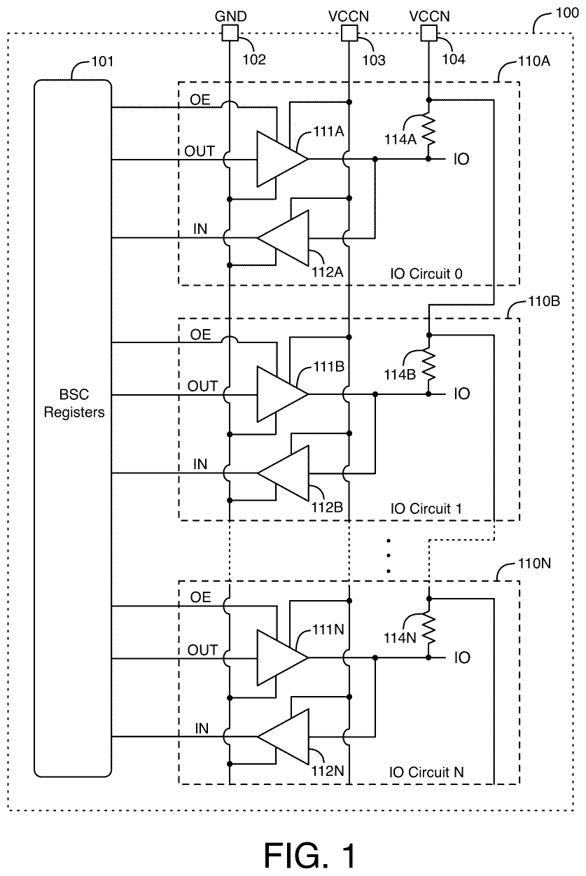

FIG. 1 is a diagram illustrating a portion of an integrated circuit (IC) die 100 that includes boundary scan chain (BSC) registers 101 and an N number of input and output (IO) circuits 110. In the example of Figure (FIG. 1, N is any integer greater than 2. Three of the IO circuits 110 (i.e., IO circuits 110A, 110B, and 110N) are shown in FIG. 1 as an example. According to various examples, an IC implementing techniques disclosed herein can include any number of IO circuits 110 (e.g., 2, 3, 4, 5, 6, etc. IO circuits 110).

IC die 100 (also referred to herein as IC 100) also includes external conductive pads 102, 103, and 104 and an N number of external conductive pads IO. External contacts of an integrated circuit include external conductive pads, pins, etc. The IC 100 of FIG. 1 can be any type of electronic integrated circuit (IC) device, such as a configurable logic IC (e.g., a field programmable gate array or FPGA), a microprocessor IC, a graphics processing unit IC, a transceiver IC, a memory IC, an application specific integrated circuit (ASIC), or a structured ASIC. IC 100 can be housed in an IC package. The BSC registers 101 can be, for example, JTAG (Joint Test Action Group) BSC registers.

Each of the IO circuits 110 includes an output buffer circuit 111, an input buffer circuit 112, and a weak pull circuit 114. For example, IO circuit 110A includes output buffer circuit 111A, input buffer circuit 112A, and weak pull circuit 114A. IO circuit 110B includes output buffer circuit 111B, input buffer circuit 112B, and weak pull circuit 114B. IO circuit 110N includes output buffer circuit 111N, input buffer circuit 112N, and weak pull circuit 114N. The IC 100 can include any number of IO circuits 110, including possibly IO circuits 110 that are not shown in FIG. 1. IO circuit 110N is shown as coupled to IO circuit 110B through dotted lines in FIG. 1 to indicate that additional IO circuits 110 may be coupled between IO circuits 110B and 110N. The dotted lines represent possible connections to other IO circuits 110. In other examples, an IC implementing techniques disclosed herein can include any number of input and/or output buffer circuits in each IO circuit 110. Each of the circuits 111-112 and 114 in each IO circuit 110 is coupled to an external input/output pad IO of IC 100.

The weak pull circuit 114 in each IO circuit 110 is a resistive circuit that can be implemented, as examples, by a passive resistor or by one or more transistors that are biased to generate a weak pullup current. The weak pull circuit 110 is configurable to function as a weak pullup circuit. The weak pull circuit 114 in each IO circuit 110 is coupled between the external pad 104 and the external input/output pad IO in the respective IO circuit 110, as shown in FIG. 1. A supply voltage VCCN can be provided through pad 104 to each of the weak pull circuits 114 through a first power supply voltage network in the IC 100 during a user mode of operation.

The data input of the output buffer circuit 111 in each IO circuit 110 is coupled to the BSC registers 101, and the data output of the output buffer circuit 111 in each IO circuit 110 is coupled to the pad IO in the respective IO circuit 110. The BSC registers 101 can generate output enable signals OE and output data signals OUT and can receive input signals IN. Each of the IO circuits 110 includes a user mode of operation in which the supply voltage VCCN is applied externally to the respective resistive circuit 114 through the external pad 104. During the user mode of operation, any of the output buffer circuits 111 can be enabled by a respective one of the output enable signals OE to drive a respective one of the output data signals OUT from the BSC registers 101 to the respective pad IO using the respective weak pull circuit 114.

The data output of the input buffer circuit 112 in each IO circuit 110 is coupled to the BSC registers 101, and the data input of the input buffer circuit 112 in each IO circuit 110 is coupled to the pad IO in the respective IO circuit 110. During the user mode of operation, any of the input buffer circuits 112 can drive a respective one of the input data signals IN from the respective pad IO to the BSC registers 101.

The external pad 102 is coupled to a ground input of the output buffer circuit 111 in each IO circuit 110 and to a ground input of the input buffer circuit 112 in each IO circuit 110 through a ground voltage network in IC 100. A ground voltage GND can be provided from pad 102 through the ground voltage network in IC 100 to each of the output buffer circuits 111 and to each of the input buffer circuits 112 in the IO circuits 110. The external pad 103 is coupled to a supply input of the output buffer circuit 111 in each IO circuit 110 and to a supply input of the input buffer circuit 112 in each IO circuit 110 through a second power supply voltage network in IC 100. The power supply voltage VCCN can be provided from pad 103 through the second power supply voltage network in IC 100 to each of the output buffer circuits 111 and to each of the input buffer circuits 112 in IO circuits 110.

The weak pull circuit 114 in each IO circuit 110 can be used to test the leakage currents in the respective IO circuit 110 during a test mode of operation. The weak pull circuits 114 can be used to achieve precise and highly accurate leakage current measurements in IO circuits 110 with resolution in the range of microamperes. In some examples, the techniques disclosed herein may not require design-for-test circuitry to be added to IC 100.

The leakage current testing techniques disclosed herein can increase test quality and reduce IC yield loss compared to previously known methods. The leakage current testing techniques disclosed herein can be used to group test multiple IO circuits 110 to check leakage current to external power and ground pads using a single test pattern in a substantially reduced period of time (e.g., 30%) compared to existing NTL testing methods. The leakage resistance can cover, for example, up to 100 kiloohms or better. The leakage current testing techniques disclosed herein can also be used for failure analysis and debugging isolation that targets individual IO circuits with finer measurement resolution. The leakage current testing techniques can be controlled externally so that tests can be easily ported across IC products, while providing different leakage specifications through control voltage adjustment.

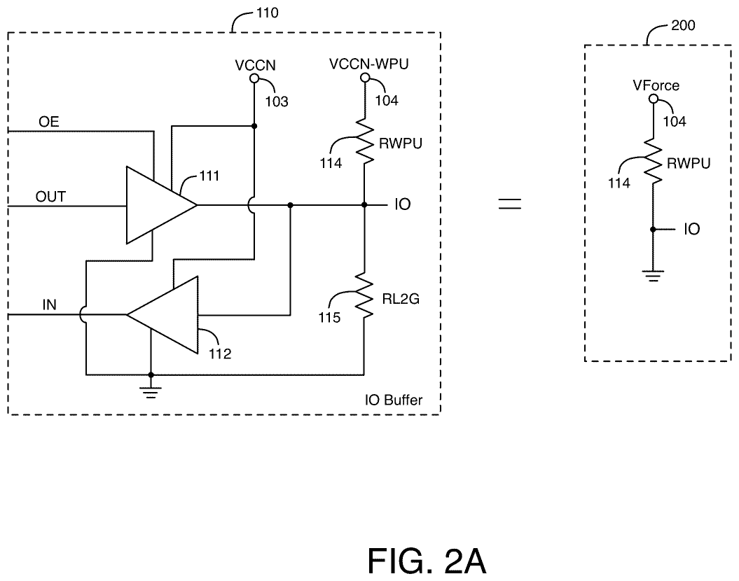

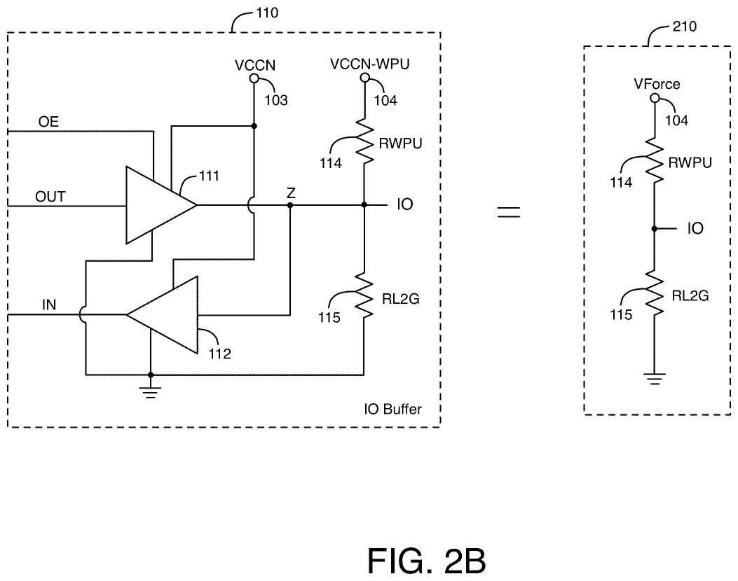

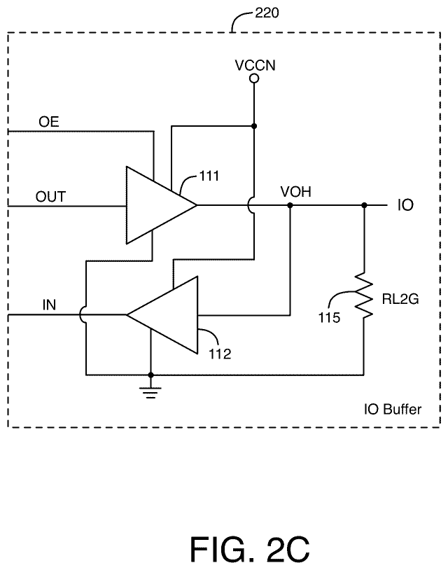

Each of the weak pull circuits 114 receives the supply voltage VCCN through a power supply voltage network in IC 100 to provide a weak pullup current to one of pads IO. The weak pull circuits 114 allow an external parametric measurement unit (PMU) to access the IO circuits 110 through the external pad 104 to perform Force Voltage Measurement Current (FVMC) tasks during a test mode of operation. The FVMC tasks can, as an example, be divided into first and second steps that can be performed during the test mode of operation to obtain a final leakage current value in each one of the IO circuits 110. FIGS. 2A-2C disclosed herein illustrate examples of how leakage current to ground values can be obtained.

An example of the first step that can be performed to obtain a final leakage current value in the test mode of operation is now described. In this example, the first step involves mimicking a worst-case scenario when the IO circuit 110 is shorted to ground. By performing the first step, the worst-case leakage current to ground can be obtained as an FVMC task. During the first step, the PMU measures the current through weak pull circuit 114 from pad 104 while applying a force voltage Vforce to pad 104 and while output buffer circuit 111 is enabled by output enable signal OE. The PMU can adjust the force voltage Vforce according to a product specification (e.g., the force voltage Vforce can equal supply voltage VCCN at pad 104). The force voltage Vforce can also be adjusted based on power consumption and current resolution of the IC.

FIG. 2A is a diagram that illustrates an example in which an IO circuit 110 in IC 100 contains leakage current to ground. In the example of FIG. 2A, the IO circuit 110 contains a defect that causes the IO circuit 110 to be indirectly shorted to the ground voltage network through output buffer circuit 111. Also, in the example of FIG. 2A, the output buffer circuit 111 is enabled by signal OE and turned on in response to the output data signal OUT being a logic 0 in the first step of the test mode of operation. The weak pull circuit 114 receives a supply voltage VCCN-WPU that is separate from the supply voltage VCCN provided to buffer circuits 111-112. Resistor 115 RL2G in FIG. 2A represents the defect that causes the short and leakage current to ground.

FIG. 2A shows the equivalent IO circuit 200 containing the defect that causes the short to ground when the output buffer circuit 111 is enabled by the output enable signal OE and the output buffer circuit 111 is turned on in response to the output data signal OUT to drive a logic 0 in the output signal to the pad IO. Equation (1) below is based on circuit 200. Equation (1) can be used during the first step (e.g., by a computer system) to calculate the total Weak Pullup Resistance (RWPU) of the weak pull circuit 114 using the force voltage Vforce applied by the PMU and the current measured by the PMU through pad 104 after applying the force voltage Vforce at pad 104 in the first step. The current measured by the PMU through pad 104 in the first step is referred to as Imeasure1 in equation (1).

$$RWPU = Vforce / Imeasure 1 \qquad ( 1 )$$

After the resistance value RWPU is determined using equation (1) in the first step, the resistance value RWPU can be used (e.g., by the computer system) to determine the final leakage current resistance RL2G 115 in the second step of the test mode of operation. Before the second step, each of the input and output buffers 111 and 112 in the IO circuit 110 being tested are placed in tristate mode (i.e., are disabled from driving input and output signals) so that the FVMC tasks performed can be used to obtain an accurate leakage current value in the second step of the test mode of operation. Output buffer circuit 111 is disabled by the output enable signal OE.

FIG. 2B is a diagram that illustrates an example of the IO circuit 110 being tested and an equivalent IO circuit 210 in the second step of the test mode of operation. The equivalent IO circuit 210 represents IO circuit 110 in the second step when the output buffer circuit 111 is disabled/tri-stated by the output enable signal OE and the input buffer circuit 112 is also disabled/tri-stated. The equivalent IO circuit 210 includes resistances 114-115 coupled between pad 104 at Vforce and ground. In the second step, the PMU measures a current through pad 104, while the PMU applies the force voltage Vforce to the pad 104 from outside IC 100, and while the buffer circuits 111-112 are disabled. The PMU applies the same force voltage Vforce to pad 104 in the second step that was applied to pad 104 in the first step.

Equation (2) below can be used to calculate the resistance RL2G 115 in the second step. In equation (2), the current measured by the PMU during the second step is referred to as Imeasure2. The force voltage Vforce in equation (2) is the same force voltage Vforce applied to pad 104 during the first step and used in equation (1). By superposition, the resistance RWPU and the force voltage Vforce are applied from the first step to equation (2), and the leakage current to ground resistance RL2G 115 can be calculated using equation (2).

$$RL 2 G = ( Vforce / Imeasure 2 ) - RWPU \qquad ( 2 )$$

The outcome of the test can be determined to be a pass or a fail based on the value of RL2G or Imeasure2. A value of Imeasure2 that is close to the value of Imeasure1 means that the leakage current in the IO circuit 110 is getting larger. The value of the resistance RL2G 115 is inversely proportional to the value of the current Imeasure2, such that the greater the resistance RL2G 115, the lower the value of Imeasure2. The resistance RL2G 115 can be used to determine the leakage current to ground.

FIG. 2C is a diagram that illustrates an example of a user leakage current to ground circuit 220 that is an equivalent of the IO circuit 110 of FIG. 2A containing a defect that causes leakage current to ground. In FIG. 2C, the output buffer circuit 111 is enabled by enable signal OE to drive a high output voltage VOH (i.e., a logic 1) from signal OUT to output pad IO. The high output voltage VOH and the actual leakage current to ground Ileak2gnd through resistance RL2G 115 can, for example, be obtained from a product specification document for IC 100. The high voltage VOH and the leakage current Ileak2gnd can be applied to equation (3) below, and then the resistance RL2G 115 can alternatively be calculated using equation (3). A pass or fail limit for RL2G 115 can be applied in the second step.

$$RL 2 G = VOH / Ileak 2 gnd \qquad ( 3 )$$

If the user uses leakage current Imeasure2 as a pass or fail limit in the second step, the user can substitute RL2G obtained from equation (3) into equation (4) below to derive current Imeasure2.

$$Imeasure 2 = Vforce / ( RL 2 G + RWPU ) \qquad ( 4 )$$

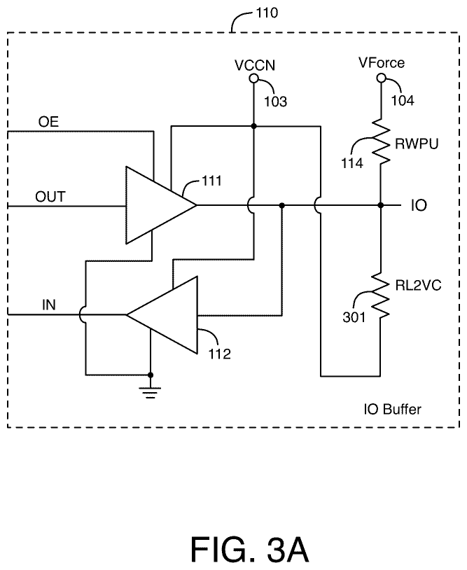

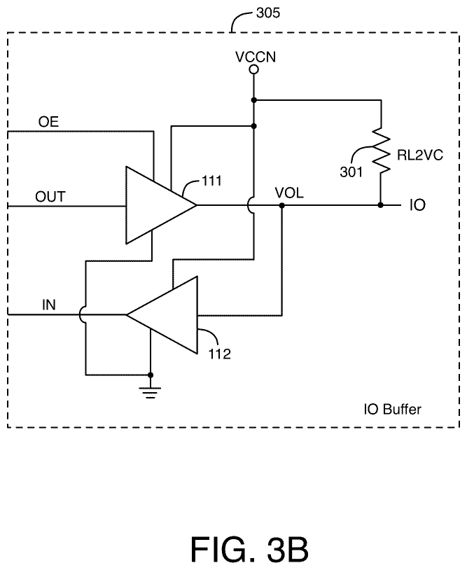

FIG. 3A is a diagram that illustrates an example in which an IO circuit 110 in IC 100 contains leakage current to the supply voltage network. In the example of FIG. 3A, the IO circuit 110 contains a defect that causes the IO circuit 110 to be indirectly shorted to the supply voltage network that provides supply voltage VCCN at pad 103. FIG. 3A shows the equivalent IO circuit containing the defect that causes the short to the supply voltage network. Resistance 301 RL2VC in FIG. 3A represents the defect that causes the short to the supply voltage network coupled to pad 103. In FIG. 3A, the resistance 301 RL2VC is coupled between external pad IO and a node at the supply voltage network that provides supply voltage VCCN to buffer circuits 111-112 from pad 103.

In order to obtain the leakage current to the supply voltage network, a user can initially apply the first step and equation (1) described above with respect to FIG. 2A to obtain the resistance RWPU of the weak pull circuit 114. In the second step, Vforce is replaced in equation (2) with supply voltage VCCN in equation (5) below. When performing the FVMC tasks, a force voltage Vforce of 0 volts is applied to the weak pull circuit 114 at pad 104 as shown in FIG. 3A in the second step, while the output buffer circuit 111 is disabled, and the PMU measures the current through pad 104.

Equation (5) below can be used to calculate the resistance 301 RL2VC in the second step. In equation (5), the current measured by the PMU through pad 104 during the second step is referred to as Imeasure2. The resistance RWPU from the first step and the supply voltage VCCN are applied to equation (5) below, and then the leakage current to the supply voltage network resistance RL2VC 301 can be calculated using equation (5).

$$RL 2 VC = ( VCCN / Imeasure 2 ) - RWPU \qquad ( 5 )$$

FIG. 3B is a diagram that illustrates an example of a user circuit 305 that is an equivalent of the IO circuit 110 of FIG. 3A containing a defect that causes leakage current to the supply voltage network. In FIG. 3B, the output buffer circuit 111 is enabled by enable signal OE to drive a low output voltage VOL from signal OUT to output pad IO. The low output voltage VOL of output buffer circuit 111 and the leakage current Ileak2vccn to the supply voltage network VCCN can, for example, be obtained from a product specification document for IC 100. These values can be applied to equation (6) below to calculate the resistance 301 RL2VC as a pass or fail limit to detect a failure caused by the leakage current to the supply voltage network that supplies VCCN to buffer circuits 111-112.

$$RL 2 VC = ( VCCN - VOL ) / Ileak 2 vccn \qquad ( 6 )$$

The techniques described above for calculating the leakage current resistance in an IO circuit can be applied to a single IO circuit, or alternatively, to a group of IO circuits containing input/output buffer circuits to calculate the leakage current to the supply voltage and/or ground voltage networks using one or more test patterns. A group of IO circuits can be tested by driving logic 1s or 0s to the selected input and/or output buffer circuits in the group of IO circuits to recalculate the resistances RWPU of weak pull circuits 114 (e.g., as described above with respect to FIG. 2A). These techniques can reduce the overall test time (e.g., by approximately 30%) compared to previously known test sequences that have an extra JTAG boundary scan chain pattern.

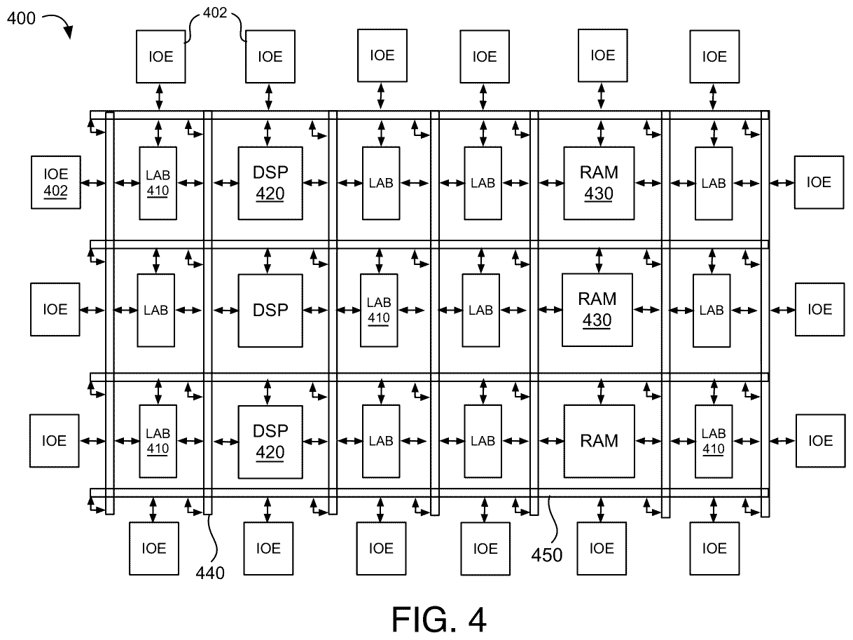

FIG. 4 is a diagram of an illustrative example of a configurable integrated circuit (IC) 400. Configurable IC 400 is an example of an IC that can include the IO circuits disclosed herein with respect to FIGS. 1, 2A-2C, and 3A-3B. As shown in FIG. 4, the configurable integrated circuit 400 includes a two-dimensional array of configurable logic circuit blocks, including logic array blocks (LABs) 410 and other configurable logic circuit blocks, such as random access memory (RAM) blocks 430 and digital signal processing (DSP) blocks 420, for example. Configurable logic circuit blocks, such as LABs 410, can include smaller configurable regions (e.g., configurable logic elements, configurable logic blocks, or adaptive logic modules (ALMs)) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 (e.g., including IO circuit blocks) for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400). The techniques disclosed herein with respect to FIGS. 1, 2A-2C, and 3A-3B can also be applied to GPIO/HSIO/OPIO circuitry.

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

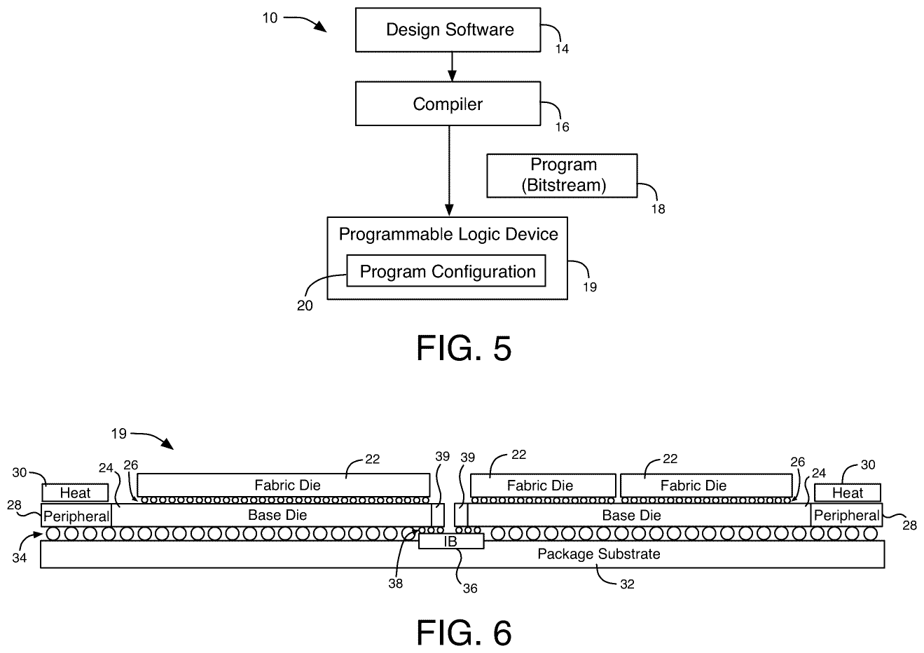

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

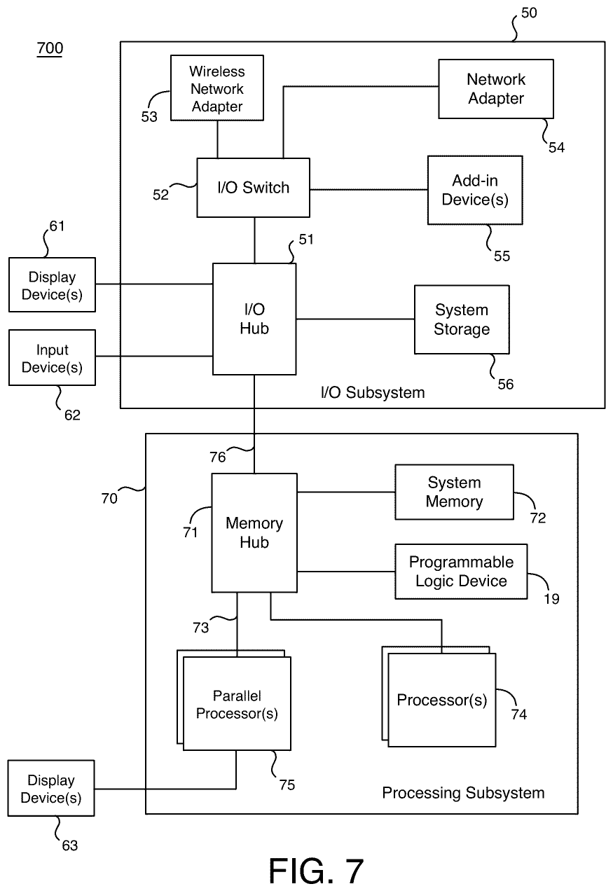

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising an output circuit, wherein the output circuit comprises: first, second, and third external contacts; a first output buffer circuit coupled to the first external contact; a first resistive circuit coupled between the first external contact and the second external contact; a second output buffer circuit coupled to the third external contact; and a second resistive circuit coupled between the second external contact and the third external contact, wherein the output circuit comprises a test mode of operation to test for leakage current on the first and the third external contacts in response to receiving a first voltage applied externally to the first and the second resistive circuits through the second external contact, and wherein the output circuit comprises a user mode of operation wherein a supply voltage is applied externally to the first and the second resistive circuits through the second external contact.

In Example 2, the integrated circuit of Example 1 may optionally include, wherein the second external contact is set to a same voltage level as a power supply of the first output buffer circuit during the user mode of operation.

In Example 3, the integrated circuit of any one of Examples 1-2 may optionally include, wherein the first resistive circuit is a weak pullup circuit.

In Example 4, the integrated circuit of any one of Examples 1-3 may optionally include, wherein the first resistive circuit comprises a resistor or a transistor.

In Example 5, the integrated circuit of any one of Examples 1˜4 further comprises an input buffer circuit coupled to the first external contact.

In Example 6, the integrated circuit of any one of Examples 1-5 further comprises: a third output buffer circuit coupled to a fourth external contact of the integrated circuit; and a third resistive circuit coupled between the second external contact and the fourth external contact, wherein the output circuit operates in the test mode of operation to test for additional leakage current on the fourth external contact in response to receiving the first voltage applied externally to the third resistive circuit through the second external contact.

In Example 7, the integrated circuit of any one of Examples 1-6 may optionally include, wherein the integrated circuit is a configurable integrated circuit comprising configurable logic circuits.

Example 8 is a method for testing an integrated circuit in a package, wherein the integrated circuit comprises first and second external pads coupled to input buffer circuits and output buffer circuits, the method comprising: using a third external pad of the integrated circuit as a test port during a leakage test by measuring a leakage current of the first and the second external pads through the third external pad; and using the third external pad to provide a power supply voltage to the integrated circuit in a user mode, wherein at least one of the first or the second external pads under test is not bonded out in the package.

In Example 9, the method of Example 8 further comprises: receiving a first voltage applied externally to first and second resistive circuits through the third external pad.

In Example 10, the method of any one of Examples 8-9 further comprises receiving a supply voltage applied externally to the first and the second resistive circuits through the third external pad in the user mode.

In Example 11, the method of any one of Examples 8-10 may optionally include, wherein a first resistive circuit is coupled between the third external pad and a first one of the output buffer circuits.

In Example 12, the method of Example 11 may optionally include, wherein a second resistive circuit is coupled between the third external pad and a second one of the output buffer circuits.

In Example 13, the method of any one of Examples 8-12 may optionally include, wherein a defect causes the leakage current between the first external pad and a ground voltage network.

In Example 14, the method of any one of Examples 8-13 may optionally include, wherein a defect causes the leakage current between the second external pad and a supply voltage network.

In Example 15, the method of any one of Examples 8-14 further comprises: enabling a first one of the output buffer circuits using an output enable signal while a first current is measured during the leakage test; and disabling the first one of the output buffer circuits using the output enable signal while a second current is measured during the leakage test.

Example 16 is an integrated circuit comprising an input circuit, wherein the input circuit comprises: first, second, and third external contacts; a first input buffer circuit coupled to the first external contact; a first resistive circuit coupled between the first external contact and the second external contact; a second input buffer circuit coupled to the third external contact; and a second resistive circuit coupled between the second external contact and the third external contact, wherein the input circuit comprises a test mode of operation to test for leakage current on the first and the third external contacts in response to receiving a first voltage applied externally to the first and the second resistive circuits through the second external contact, and wherein the input circuit comprises a user mode of operation wherein a supply voltage is applied externally to the first and the second resistive circuits through the second external contact.

In Example 17, the integrated circuit of Example 16 may optionally include, wherein the second external contact is set to a same voltage level as the supply voltage during the user mode of operation, and the supply voltage is provided to the first and the second input buffer circuits.

In Example 18, the integrated circuit of any one of Examples 16-17 may optionally include, wherein the first resistive circuit comprises a resistor or a transistor.

In Example 19, the integrated circuit of any one of Examples 16-18 may optionally include, wherein the first resistive circuit is a weak pullup circuit.

In Example 20, the integrated circuit of any one of Examples 16-19 may optionally include, wherein a defect causes the leakage current between the first external contact and a voltage network in the electronic device.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising an output circuit, wherein the output circuit comprises:
first, second, and third external contacts;
a first output buffer circuit coupled to the first external contact;
a first resistive circuit coupled between the first external contact and the second external contact;
a second output buffer circuit coupled to the third external contact; and
a second resistive circuit coupled between the second external contact and the third external contact,
wherein the output circuit comprises a test mode of operation to test for leakage current on the first and the third external contacts in response to receiving a first voltage applied externally to the first and the second resistive circuits through the second external contact, and
wherein the output circuit comprises a user mode of operation wherein a supply voltage is applied externally to the first and the second resistive circuits through the second external contact.

2. The integrated circuit of claim 1, wherein the second external contact is set to a same voltage level as a power supply of the first output buffer circuit during the user mode of operation.

3. The integrated circuit of claim 1, wherein the first resistive circuit is a weak pullup circuit.

4. The integrated circuit of claim 1, wherein the first resistive circuit comprises a resistor or a transistor.

5. The integrated circuit of claim 1 further comprising:
an input buffer circuit coupled to the first external contact.

6. The integrated circuit of claim 1 further comprising:
a third output buffer circuit coupled to a fourth external contact of the integrated circuit; and
a third resistive circuit coupled between the second external contact and the fourth external contact,
wherein the output circuit operates in the test mode of operation to test for additional leakage current on the fourth external contact in response to receiving the first voltage applied externally to the third resistive circuit through the second external contact.

7. The integrated circuit of claim 1, wherein the integrated circuit is a configurable integrated circuit comprising configurable logic circuits.

8. A method for testing an integrated circuit in a package, wherein the integrated circuit comprises first and second external pads coupled to input buffer circuits and output buffer circuits, the method comprising:
using a third external pad of the integrated circuit as a test port during a leakage test by measuring a leakage current of the first and the second external pads through the third external pad; and
using the third external pad to provide a power supply voltage to the integrated circuit in a user mode, wherein at least one of the first or the second external pads under test is not bonded out in the package.

9. The method of claim 8 further comprising:
receiving a first voltage applied externally to first and second resistive circuits through the third external pad during the leakage test.

10. The method of claim 9 further comprising:
receiving a supply voltage applied externally to the first and the second resistive circuits through the third external pad in the user mode.

11. The method of claim 8, wherein a first resistive circuit is coupled between the third external pad and a first one of the output buffer circuits.

12. The method of claim 11, wherein a second resistive circuit is coupled between the third external pad and a second one of the output buffer circuits.

13. The method of claim 8, wherein a defect causes the leakage current between the first external pad and a ground voltage network.

14. The method of claim 8, wherein a defect causes the leakage current between the second external pad and a supply voltage network.

15. The method of claim 8 further comprising:
enabling a first one of the output buffer circuits using an output enable signal while a first current is measured during the leakage test; and
disabling the first one of the output buffer circuits using the output enable signal while a second current is measured during the leakage test.

16. An integrated circuit comprising an input circuit, wherein the input circuit comprises:
first, second, and third external contacts;
a first input buffer circuit coupled to the first external contact;
a first resistive circuit coupled between the first external contact and the second external contact;
a second input buffer circuit coupled to the third external contact; and
a second resistive circuit coupled between the second external contact and the third external contact,
wherein the input circuit comprises a test mode of operation to test for leakage current on the first and the third external contacts in response to receiving a first voltage applied externally to the first and the second resistive circuits through the second external contact, and
wherein the input circuit comprises a user mode of operation wherein a supply voltage is applied externally to the first and the second resistive circuits through the second external contact.

17. The integrated circuit of claim 16, wherein the second external contact is set to a same voltage level as the supply voltage during the user mode of operation, and the supply voltage is provided to the first and the second input buffer circuits.

18. The integrated circuit of claim 16, wherein the first resistive circuit comprises a resistor or a transistor.

19. The integrated circuit of claim 16, wherein the first resistive circuit is a weak pullup circuit.

20. The integrated circuit of claim 16, wherein a defect causes the leakage current between the first external contact and a voltage network in the electronic device.
